(19) United States
(12) Patent Application Publication
(10) Pub. No.: US 2026/0204935 A1
(43) Pub. Date: Jul. 16, 2026

(54) POWER BANK

(71) Applicant: Anker Innovations Technology Co., Ltd., CHANGSHA (CN)

(72) Inventor: Bin LI, SHENZHEN (CN)

(21) Appl. No.: 19/444,513

(22) Filed: Jan. 9, 2026

(30) Foreign Application Priority Data
Jan. 10, 2025 (CN) 202510048064.7
Jan. 10, 2025 (CN) 202520068199.5

(51) Int. Cl. H02J 7/70; H05K 5/00; H05K 5/02; H05K 5/30

(52) U.S. Cl. CPC H02J 7/731; H05K 5/0052; H05K 5/0065; H05K 5/0086; H05K 5/0226; H05K 5/0247; H05K 5/30

(57) ABSTRACT

The present application provides a power bank including a first shell, a battery, a circuit board, a second shell, a connection terminal, an electrical connection assembly, a first rotation structure, and a second rotation structure. The circuit board is electrically connected to the battery, and the battery and the circuit board are disposed inside the first shell. The connection terminal is disposed on the second shell, and the electrical connection assembly is electrically connected to the connection terminal and the circuit board. The first rotation structure is connected to the connection terminal and the second shell, so that the connection terminal is able to be rotated relative to the second shell. The second rotation structure is connected to the first shell and the second shell, so that the first shell is able to be rotated relative to the second shell.

### CROSS-REFERENCE TO RELATED APPLICATIONS

The present application claims priorities to Chinese Patent Application No. 202510048064.7, filed on Jan. 10, 2025, and Chinese Patent Application No. 202520068199.5, filed on Jan. 10, 2025, both of which are herein incorporated by reference in their entirety.

### TECHNICAL FIELD

The present disclosure relates to the technical field of power banks, and in particular to a power bank.

### BACKGROUND

In related art, a body of a power bank is integrated with a charging terminal. The charging terminal can rotate around the power bank, so that the charging terminal can extend out of the power bank in a case where charging is performed, and the charging terminal can be stored in the power bank in a case where the charging is not performed. However, a charging interface of a mobile phone is usually disposed on a bottom of the mobile phone. In a case where charging is performed by establishing a plug-in connection between the mobile phone and the charging terminal, the charging terminal or the power bank is only in contact with the bottom of the mobile phone, resulting in poor support for the mobile phone. Therefore, in a case where the mobile phone is charged, support stability provided by the power bank is poor.

### SUMMARY OF THE DISCLOSURE

The embodiments of the present disclosure provide a power bank including a first shell, a battery, a circuit board, a second shell, a connection terminal, an electrical connection assembly, a first rotation structure, and a second rotation structure. The circuit board is electrically connected to the battery, and the battery and the circuit board are disposed inside the first shell. The connection terminal is disposed on the second shell, and the connection terminal includes an input end and an output end. The electrical connection assembly is electrically connected to the input end of the connection terminal to the circuit board. The power bank is able to be in a first state. In a case where the power bank is in the first state, the output end of the connection terminal is disposed facing the first shell. The first rotation structure is connected to the connection terminal and the second shell, so that the connection terminal is able to be rotated relative to the second shell. The second rotation structure is connected to the first shell and the second shell, so that the first shell is able to be rotated relative to the second shell.

### BRIEF DESCRIPTION OF THE DRAWINGS

In order to more clearly describe the technical solutions in some embodiments of the present disclosure, hereinafter, the accompanying drawings that are used in the description of some embodiments will be briefly described. Obviously, the accompanying drawings in the description below merely show some embodiments of the present disclosure. For those of ordinary skill in the art, other accompanying drawings may be obtained based on these accompanying drawings without any creative efforts.

FIG. 1 is a structural schematic view of a power bank in an embodiment of the present disclosure.

FIG. 2 is a partial structural schematic view of a power bank in another embodiment of the present disclosure.

FIG. 3 is a structural schematic view of a power bank in yet another embodiment of the present disclosure.

FIG. 4 is a partial structural schematic view of a power bank in yet another embodiment of the present disclosure.

FIG. 5 is a structural schematic view of a power bank in yet another embodiment of the present disclosure.

FIG. 6 is a partial structural schematic view of a power bank in an embodiment of the present disclosure.

FIG. 7 is a partial structural schematic view of a power bank in an embodiment of the present disclosure.

FIG. 8 is a partial structural schematic view of a power bank in an embodiment of the present disclosure.

FIG. 9 is a partial structural schematic view of a power bank in an embodiment of the present disclosure.

FIG. 10 is a partial structural schematic view of a power bank in an embodiment of the present disclosure.

FIG. 11 is a partial structural schematic view of a power bank in an embodiment of the present disclosure.

FIG. 12 is a partial exploded side view of a power bank in an embodiment of the present disclosure.

FIG. 13 is a partial structural schematic view of a power bank in an embodiment of the present disclosure.

FIG. 14 is a structural schematic view illustrating a cooperation of a limiting member and a limiting part in an embodiment of the present disclosure.

FIG. 15 is a structural schematic view illustrating a cooperation of the limiting member and the limiting part in another embodiment of the present disclosure.

FIG. 16 is a structural schematic view of a power bank in yet another embodiment of the present disclosure.

FIG. 17 is a structural block view illustrating a reset member, a connection terminal, and a second shell in an embodiment of the present disclosure.

FIG. 18 is a structural block view illustrating the reset member, a first rotation structure, and the second shell in an embodiment of the present disclosure.

FIG. 19 is a structural block view illustrating a first driving member and the first rotation structure in an embodiment of the present disclosure.

FIG. 20 is a structural block view illustrating a second driving member and a second rotation structure in an embodiment of the present disclosure.

### DETAILED DESCRIPTION

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

It should be noted that all directional indications (such as up, down, left, right, front, rear, or the like) in some embodiments of the present disclosure are only configured to explain a relative position relationship between components in a specific posture (as shown in the accompanying drawings), a motion situation between the components in the specific posture (as shown in the accompanying drawings), or the like. When the specific posture is changed, the directional indication is also changed accordingly.

In addition, the terms “first” and “second” in the present disclosure are only configured to describe and cannot be understood as indicating or implying relative importance or implicitly indicating the quantity of technical features indicated. Therefore, features that are defined as “first” and “second” may explicitly or implicitly include at least one of these features. In the description of the present disclosure, “multiple” or “plurality” means at least two, such as two, three, etc., unless otherwise expressly and specifically qualified.

In the present disclosure, unless otherwise expressly specified and limited, the terms “connection” and “fixation” should be broadly understood. For example, the term “fixation” may be a fixed connection, a detachable connection, or an integrated connection. The term “connection” may be a mechanical connection or an electrical connection. The term “connection” may be a direct connection or an indirect connection through an intermediate medium. The term “connection” may be internal communication of two elements or an interaction relationship between two elements, unless otherwise expressly specified. For those of ordinary skill in the art, the specific meanings of the above terms in the embodiments of the present disclosure may be understood according to the specific situation.

In addition, the technical solutions of any two of various embodiments in the present disclosure can be combined with each other, but the combination must be able to be implemented by those of ordinary skill in the art. When the combination of the technical solutions is contradictory or cannot be implemented, it should be considered that this combination of the technical solutions does not exist and is not within protection scope required by the present disclosure.

The embodiments of the present disclosure provide a power bank that can improve support for a mobile phone and improve stability during charging the mobile phone.

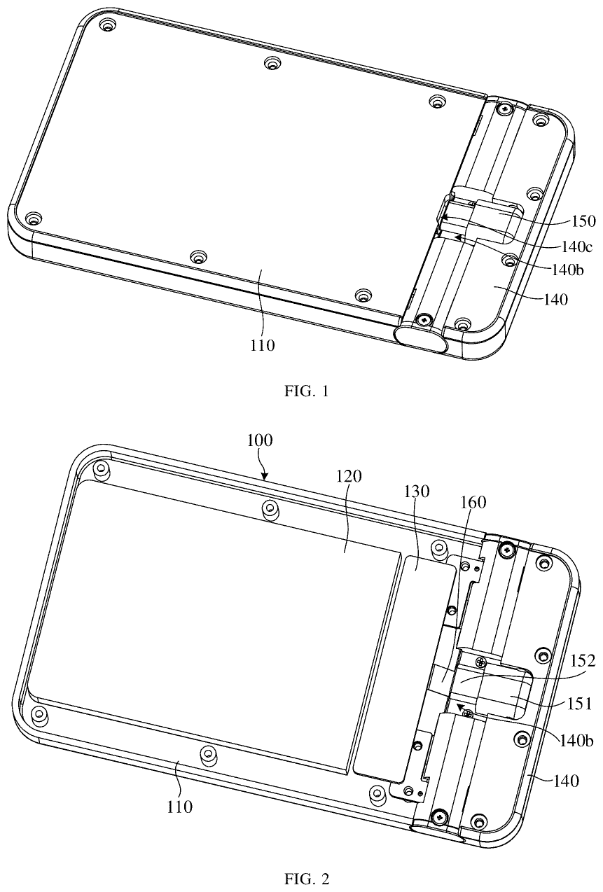

As illustrated in FIGS. 1 to 5, embodiments of the present disclosure provide a power bank 100 including a first shell 110, a battery 120, a circuit board 130, a second shell 140, a connection terminal 150, an electrical connection assembly 160, a first rotation structure 170, and a second rotation structure 180.

The battery 120 is configured to store electrical energy and to release the electrical energy in a case where release of the electrical energy is needed. In some embodiments, a type of the battery 120 may be a steel shell battery 120 or a soft pack battery 120. In some embodiments, a shape of the battery 120 may be cylindrical, square, etc. In some embodiments, capacity of the battery 120 may be any value in a range from 2000 mAh to 30000 mAh. The circuit board 130 is electrically connected to the battery 120. The circuit board 130 is a charging and discharging circuit board suitable for the power bank 100, and the circuit board 130 has a built-in charging management chip. The circuit board 130 is configured to control charging and discharging of the battery 120. In some embodiments, the charging management chip and related circuits on the circuit board 130 may perform charging, discharging, power detection, voltage detection and other operations on the battery 120. The charging management chip and the related circuits may also have protection functions such as overcharging, overdischarging, overcurrent temperature control, short circuit protection, etc., thereby extending service life of the battery 120 and improving safety of the battery 120 during use.

Both the battery 120 and the circuit board 130 are disposed inside the hollow first shell 110. The first shell 110 may limit and fix the battery 120 and the circuit board 130, while also protecting the battery 120 and the circuit board 130. In some embodiments, a material of the first shell 110 may be plastic, so that a complex shape can be manufactured at a relatively low cost, and an insulating effect can be provided. In some embodiments, the material of the first shell 110 may be metal, so that the first shell 110 has high strength, and accordingly, the first shell 110 has a longer service life. In some embodiments, a shape of the first shell 110 may be plate-shaped, so that the first shell 110 has a relatively thin thickness.

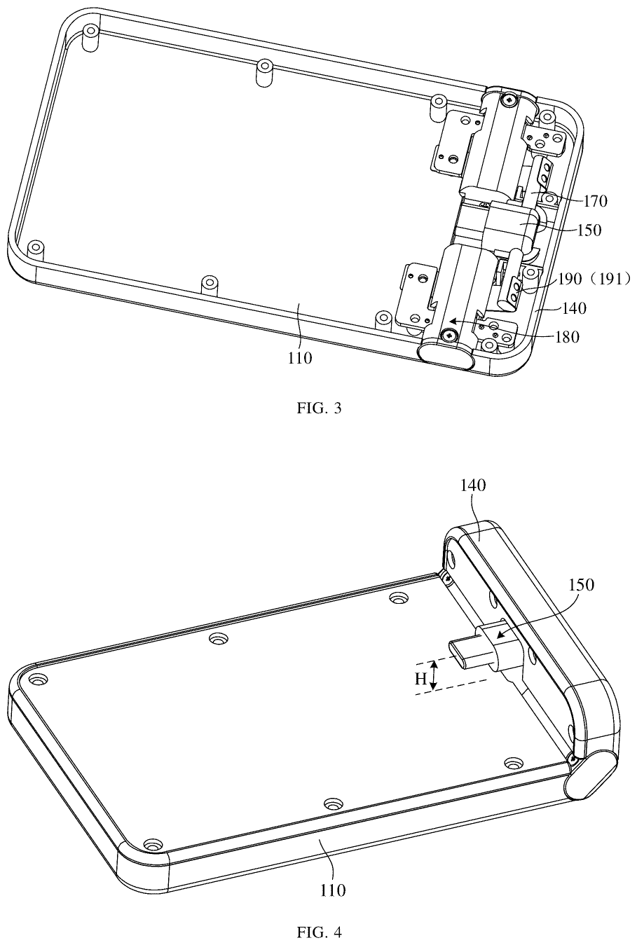

As illustrated in FIG. 2, the connection terminal 150 includes an input end 151 and an output end 152 connected to the input end 151. The output end 152 of the connection terminal 150 is configured to achieve a plug-in connection with an electronic device, thereby supplying power to the electronic device. In some embodiments, the electronic device may include a mobile phone, a wireless headphone, a tablet, etc. In some embodiments, a type of the connection terminal 150 may be USB Type-C, Lighting, Micro USB, etc. The connection terminal 150 is disposed on the second shell 140, and the second shell 140 is configured to support and protect the connection terminal 150. In some embodiments, a material of the second shell 140 may be the plastic, so that the complex shape can be manufactured at the relatively low cost, and the insulating effect can be provided. In some embodiments, the material of the second shell 140 may be metal, so that the second shell 140 has the high strength, and accordingly, the second shell 140 has the longer service life. In some embodiments, a shape of the second shell 140 may be plate-shaped, so that the second shell 140 has the relatively thin thickness. During using the power bank, the output end 152 of the connection terminal 150 extends at least partially outward relative to the second shell 140, so that the connection terminal 150 is electrically connected to an external electronic device, thereby achieving power supply.

The electrical connection assembly 160 is electrically connected to the input end 151 of the connection terminal 150 and the circuit board 130, so that the electrical energy stored in the battery 120 can be conducted to the connection terminal 150 through the circuit board 130 and the electrical connection assembly 160. The electrical connection assembly 160 may be a flexible circuit or a wire. The electrical connection assembly 160 may be connected to the circuit board 130 or the connection terminal 150 by soldering. The electrical connection assembly 160 may also be connected to the circuit board 130 or the connection terminal 150 by using a plug-in cable socket.

The first rotation structure 170 is connected to the connection terminal 150 and the second shell 140, so that the connection terminal 150 is able to be rotated relative to the second shell 140. In a case where the charging is required, the connection terminal 150 is able to be rotated to form an angle with the second shell 140, so that the electronic device is able to establish a plug-in cooperation with the connection terminal 150. In some embodiments, the angle between the connection terminal 150 and the second shell 140 may be greater than or equal to 0 degrees and less than or equal to 90 degrees. In a case where the charging is not required, the connection terminal 150 is able to be rotated, so that the connection terminal 150 is attached to the second shell 140. This can reduce protrusion of the connection terminal 150 relative to the second shell 140, so that the power bank 100 is more portable, and probability of scraping and bumping of the connection terminal 150 is reduced. As illustrated in FIG. 1, in some embodiments, a groove 140b is defined on the second shell 140, and the connection terminal 150 may be at least partially stored in the groove 140b, or may extend from the groove 140b in a case where the power bank is in a second state, so that an outer surface of the second shell 140 is relatively flat, further improving the portability of the power bank 100 and reducing the probability of the connection terminal 150 being scraped by an external object. The connection terminal 150 is at least partially hidden inside the second shell 140, providing better safety during use.

The second rotation structure 180 is connected to the first shell 110 and the second shell 140, so that the first shell 110 is able to be rotated relative to the second shell 140. In some embodiments, along a length extending direction of the first shell 110, the second rotation structure 180 is disposed between the first shell 110 and the first rotation structure 170. In a case where the charging is required, the first shell 110 may be rotated to form an angle with the second shell 140, and the connection terminal 150 may be rotated to be substantially parallel to the first shell 110. In a case where the electronic device establishes the plug-in cooperation with the connection terminal 150, the first shell 110 can be in contact with a front surface or a back surface of the electronic device, providing support for the electronic device, thereby ensuring high stability during charging the electronic device. Moreover, the first shell 110 may be in contact with the front surface or the back surface of the electronic device, that is, the first shell 110 and the electronic device may be stacked on each other. Therefore, an overall volume of an assembly formed by the electronic device and the power bank 100 is relatively small in a case where the electronic device is charged by using the power bank 100, occupying a relatively regular space, so that the power bank 100 is more portable. In a case where the charging is not required, the first shell 110 may be rotated to be parallel to the second shell 140, thereby making appearance of the power bank 100 more regular, presenting an integrated design. Therefore, the power bank 100 is more portable, and the power bank 100 is less prone to being scratched by the external object.

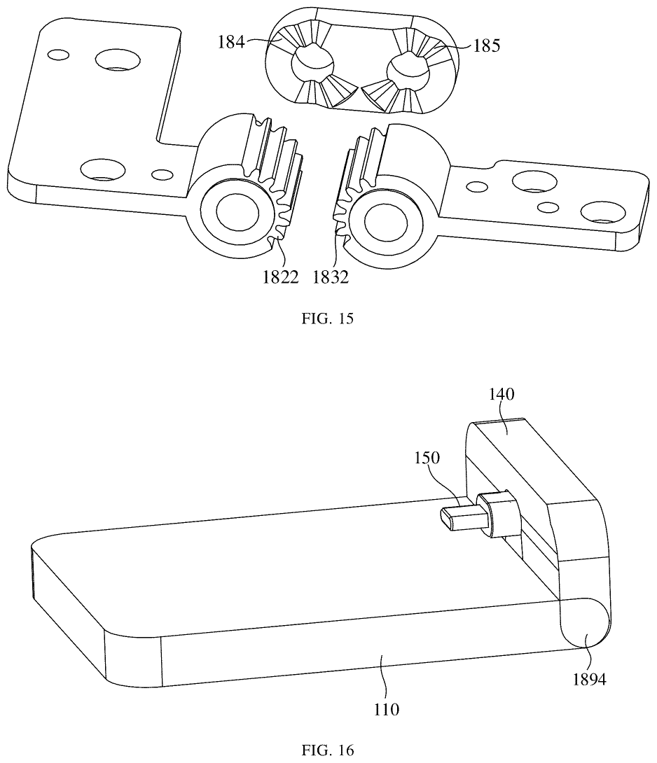

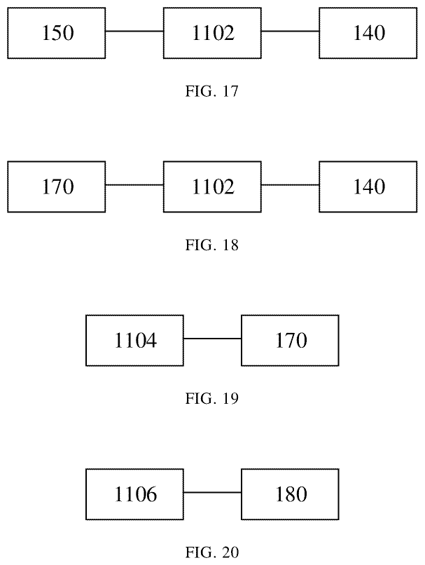

In some embodiments, as illustrated in FIGS. 17 and 18, the power bank 100 further includes a reset member 1102, the reset member 1102 is connected to the connection terminal 150 and the second shell 140, or the reset member 1102 is connected to the first rotation structure 170 and the second shell 140, so that the connection terminal 150 has a restoring force that is configured to rotate the connection terminal 150 to be parallel to the second shell 140. In a case where a user manually turns the connection terminal 150, it is necessary to overcome an elastic force of the reset member 1102. In a case where the user releases, the connection terminal 150 is able to be reset to be parallel to the second shell 140.

In some embodiments, the reset member 1102 may be a torsion spring, two force arms of the torsion spring are respectively connected to the connection terminal 150 and the second shell 140, thereby pushing the connection terminal 150 to rotate and reset. In some embodiments, the reset member 1102 may be a spring piece, both ends of the spring piece are respectively connected to the connection terminal 150 and the second shell 140, thereby pushing the connection terminal 150 to rotate and reset.

As illustrated in FIGS. 1 to 5, in some embodiments, the power bank 100 may be in a first state or a second state. As illustrated in FIGS. 1 to 3, the power bank 100 is in the first state. As illustrated in FIGS. 4 and 5, the power bank 100 is in the second state. In a case where the power bank 100 is rotated from the first state to the second state, the angle between the first shell 110 and the second shell 140 decreases. In some embodiments, the angle between the first shell 110 and the second shell 140 changes from 180 degrees to 90 degrees. It should be noted that in a case where the power bank 100 is rotated from the first state to the second state, the connection terminal 150 may be rotated or remain stationary relative to the second shell 140. That is, the angle between the connection terminal 150 and the second shell 140 may change or not change. That is, in a case where the power bank 100 is in the second state, the angle between the connection terminal 150 and the second shell 140 may be 0 degrees, 90 degrees, or any angle in a range from 0 degrees to 90 degrees.

In some embodiments, as illustrated in FIGS. 1 to 3, the power bank 100 is in the first state, and the first shell 110 is disposed parallel to the second shell 140. The parallelism defined in the present embodiment includes a situation where the first shell 110 and the second shell 140 are in the same plane. In some embodiments, the first shell 110 and the second shell 140 are substantially in the same plane, that is, a front surface of the first shell 110 is substantially flush with a front surface of the second shell 140, and a back surface of the first shell 110 is substantially flush with a back surface of the second shell 140. As illustrated in FIGS. 3 and 4, the power bank 100 is in the second state, the first shell 110 is disposed perpendicular to the second shell 140, and the connection terminal 150 is disposed parallel to the first shell 110. A charging port of the electronic device, such as the mobile phone, etc., is usually parallel to the back surface of the electronic device and disposed on a bottom of the electronic device. Therefore, in a case where the connection terminal 150 establishes the plug-in cooperation with the charging port of the electronic device, such as the mobile phone, etc., the first shell 110 is disposed parallel to the back surface of the mobile phone, which enables the first shell 110 to support the electronic device.

In some embodiments, in a case where the connection terminal 150 is rotated to be approximately parallel to the first shell 110, a distance between the connection terminal 150 and the first shell 110 is approximately equal to a distance between the charging port of the electronic device and the back surface of the electronic device, so that the electronic device is able to just fill a gap between the connection terminal 150 and the first shell 110, further improving support performance of the first shell 110 for the electronic device. The distance between the connection terminal 150 and the first shell 110 may be any value in a range from 2 mm to 20 mm.

As illustrated in FIGS. 1 and 2, in some embodiments, in a case where the power bank 100 is in the first state, the connection terminal 150 is disposed facing the first shell 110, that is, the input end 151 of the connection terminal 150 may be rotated. The input end 151 of the connection terminal 150 is disposed away from the first shell 110, so that the first rotation structure 170 may be disposed away from the first shell 110, thereby reducing arrangement difficulty.

In some embodiments, the output end 152 of the connection terminal 150 may be disposed as close as possible to the first shell 110. Therefore, under the condition that a length of the connection terminal 150 is fixed, the distance H between the connection terminal 150 and the first shell 110 may be reduced in a case where the power bank 100 is in the second state. In some embodiments, as illustrated in FIGS. 1 and 3, an avoidance groove 140c is defined on the first shell 110 and configured to accommodate the connection terminal 150, so that the connection terminal 150 can utilize a space of the first shell 110, further reducing the distance H between the connection terminal 150 and the first shell 110 in a case where the power bank 100 is in the second state.

In some embodiments, rotation amplitude of the connection terminal 150 relative to the second shell 140 is the same as rotation amplitude of the first shell 110 relative to the second shell 140. The rotation amplitude of the connection terminal 150 relative to the second shell 140 refers to angle change experienced by the connection terminal 150 during its rotation or turning relative to the second shell 140. The rotation amplitude of the first shell 110 relative to the second shell 140 refers to angle change experienced by the first shell 110 during its rotation or turning relative to the second shell 140. In some embodiments, the connection terminal 150 is rotated 90 degrees relative to the second shell 140, and the rotation amplitude of the connection terminal 150 relative to the second shell 140 is 90 degrees.

In some embodiments, a rotation direction of the connection terminal 150 relative to the second shell 140 is the same as a rotation direction of the first shell 110 relative to the second shell 140. In some embodiments, during the power bank 100 switching from the first state to the second state, i.e., during the power bank 100 rotating from the state in FIG. 1 to the state in FIG. 4, the rotation direction of the first shell 110 relative to the second shell 140 is clockwise, and the rotation direction of the connection terminal 150 relative to the second shell 140 is also clockwise.

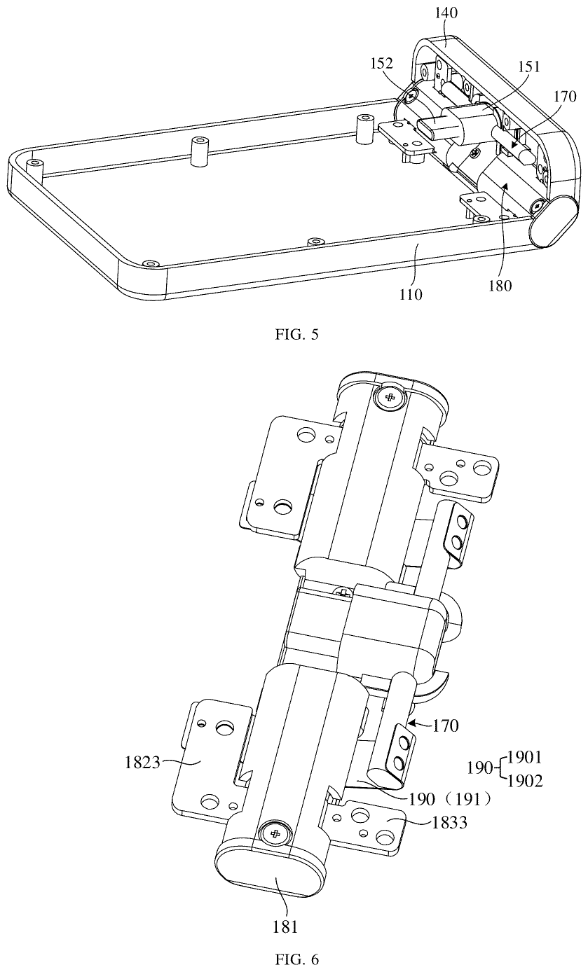

As illustrated in FIG. 6, in some embodiments, the power bank 100 further includes a linkage structure 190, and the linkage structure 190 is connected to the first rotation structure 170 and the second rotation structure 180. The second rotation structure 180 is able to drive the first rotation structure 170 to rotate through the linkage structure 190, so that the first rotation structure 170 and the second rotation structure 180 are synchronously rotated. By disposing the linkage structure 190, during driving the first shell 110 and the second shell 140 to rotate relative to each other, the connection terminal 150 can be synchronously rotated relative to the second shell 140. The user does not need to rotate the first shell 110 and the connection terminal 150 separately, saving operation steps and making the power bank 100 more convenient to use.

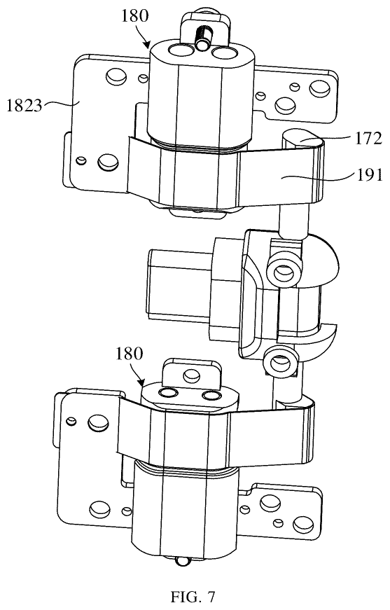

As illustrated in FIGS. 6 and 7, in some embodiments, the linkage structure 190 includes a rigid member 191. In some embodiments, a material of the rigid member 191 may be metal for durability. An end of the rigid member 191 is fixedly connected to the first rotation structure 170, and another end of the rigid member 191 is fixedly connected to the second rotation structure 180. The rotation of the second rotation structure 180 can drive the rigid member 191 to move, such as pushing and pulling the rigid member 191. The rigid member 191 further drives the first rotation structure 170 to rotate. In some embodiments, in a case where the power bank 100 is rotated from the first state to the second state, the rigid member 191 deforms to pull the first rotation structure 170 to rotate. In some embodiments, in a case where the power bank 100 is rotated from the second state to the first state, the rigid member 191 recovers its deformation to push the first rotation structure 170 to rotate. In some embodiments, in a case where the power bank 100 is rotated from the first state to the second state, the rigid member 191 deforms to push the first rotation structure 170 to rotate. In some embodiments, in a case where the power bank 100 is rotated from the second state to the first state, the rigid member 191 recovers its deformation to pull the first rotation structure 170 to rotate.

A connection between the end of the rigid member 191 and the first rotation structure 170 may be a rolling connection. The rigid member 191 is in contact with the first rotation structure 170, and there is rolling friction between the first rotation structure 170 and the rigid member 191, so that the rigid member 191 can push the first rotation structure 170 to rotate during its movement. In some embodiments, a connection between the another end of the rigid member 191 and the second rotation structure 180 may be the rolling connection. The rigid member 191 is in contact with the second rotation structure 180, and there is rolling friction between the second rotation structure 180 and the rigid member 191, so that the second rotation structure 180 can push the rigid member 191 to move during its rotation.

The rigid member 191 may experience bending or elastic deformation. Therefore, the rigid member 191 may be designed according to a shape of an internal space of the power bank 100. The rigid member 191 may be attached to components inside the power bank 100, thereby reducing occupation of the space. In some embodiments, the rigid member 191 may be attached to a part of a surface of the second rotation structure 180. In some embodiments, a crease may be preset on the rigid member 191 to define a bending position of the rigid member 191, so that the rigid member 191 may be bent in a predetermined manner. In some embodiments, by changing a connection position between the rigid member 191 and the first rotation structure 170 or a connection position between the rigid member 191 and the second rotation structure 180, a rotation direction of the first rotation structure 170 and a rotation direction of the second rotation structure 180 may be the same or opposite, and a speed ratio of the first rotation structure 170 to the second rotation structure 180 may also be adjusted.

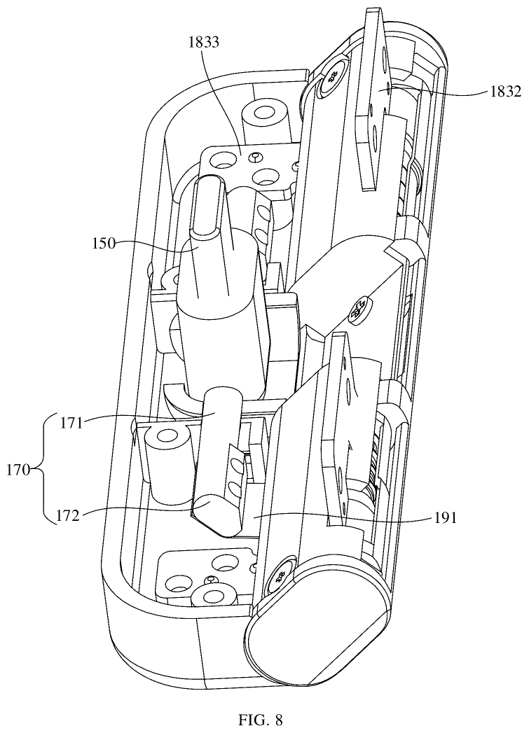

As illustrated in FIGS. 6 to 8, in some embodiments, the rigid member 191 may be a sheet-shaped structure. Therefore, the rigid member 191 has a thin thickness and occupies less space, and the rigid member 191 can pass through gaps, thereby reducing layout difficulty. In the present embodiment, the rigid member 191 acts as a transmission belt, the rigid member 191 has a certain degree of rigidity and capable of elastic deformation, thus driving the first rotation structure 170 to rotate forward or backward. In some embodiments, the rigid member 191 may surround the first rotation structure 170 or be unfolded from the first rotation structure 170, thereby reducing the space occupied by the rigid member 191 and facilitating reduction of a volume of the linkage structure 190. In some embodiments, in a case where the first rotation structure 170 is rotated from the state in FIG. 6 to the state in FIG. 8, the rigid member 191 is unfolded from the first rotation structure 170. In a case where the first rotation structure 170 is rotated from the state in FIG. 8 to the state in FIG. 6, the rigid member 191 partially surrounds the first rotation structure 170.

In some embodiments, the linkage structure 190 includes a first gear 1901 and a second gear 1902. The first gear 1901 is connected to the first rotation structure 170, and the first gear 1901 is synchronously rotated with the first rotation structure 170. The second gear 1902 is connected to the second rotation structure 180, and the second gear 1902 is synchronously rotated with the second rotation structure 180. The first gear 1901 meshes with the second gear 1902. In some embodiments, the first rotation structure 170 may include a rotation shaft fixedly connected to the first gear 1901, and the second rotation structure 180 may include a rotation shaft fixedly connected to the second gear 1902. The first rotation structure 170 and the second rotation structure 180 are linked through the first gear 1901 and the second gear 1902, and the linkage structure 190 is fixedly connected to the first rotation structure 170 and the second rotation structure 180.

In a case where the first rotation structure 170 is rotated, the first gear 1901 rotates together with the first rotation structure 170, and a rotation direction of the second gear 1902 is opposite to that of the first gear 1901, that is, in this case, the rotation direction of the first rotation structure 170 is opposite to that of the second rotation structure 180. In a case where the rotation direction of the first rotation structure 170 and the rotation direction of the second rotation structure 180 need to be the same, another gear may be disposed between the first gear 1901 and the second gear 1902 to achieve direction reversal. In some embodiments, a gear ratio of the first gear 1901 to the second gear 1902 may be 1, so that a rotation angle of the first rotation structure 170 is the same as that of the second rotation structure 180.

The linkage structure 190 may also be other transmission mechanisms. In some embodiments, the linkage structure 190 includes the transmission belt. The first rotation structure 170 is provided with a first transmission wheel, and the second rotation structure 180 is provided with a second transmission wheel. The transmission belt is sleeved on the first transmission wheel and the second transmission wheel. In this case, the linkage structure 190 is connected to the first rotation structure 170 and the second rotation structure 180 in a rolling connection manner.

The linkage structure 190 may also include a crank connecting rod mechanism, the crank connecting rod mechanism is configured to link the first rotation structure 170 and the second rotation structure 180. In some embodiments, the linkage structure 190, the first rotation structure 170, and the second rotation structure 180 may form a planar four-bar mechanism to achieve linkage.

As illustrated in FIG. 8, in some embodiments, the first rotation structure 170 includes a first rotation shaft 171, and the connection terminal 150 is fixedly connected to the first rotation shaft 171. The first rotation shaft 171 is rotatably disposed on the second shell 140, and the linkage structure 190 is connected to the first rotation shaft 171 and drives the first rotation shaft 171 to rotate.

In some embodiments, the connection terminal 150 may be rotatably disposed on the first rotation shaft 171, and the first rotation shaft 171 may be rotatably disposed on the second shell 140 or fixedly disposed on the second shell 140. The linkage structure 190 is connected to the connection terminal 150 and drives the first rotation shaft 171 to rotate. In some embodiments, the rigid member 191 is connected to the first rotation shaft 171, thereby directly driving the first rotation shaft 171 to rotate.

As illustrated in FIG. 8, in some embodiments, the first rotation structure 170 further includes a first connection member 172 disposed on the first rotation shaft 171, and the linkage structure 190 is connected to the first connection member 172 and drives the first rotation shaft 171 to rotate through the first connection member 172. In some embodiments, the rigid member 191 is connected to the first connection member 172. The first connection member 172 may be integrated with the first rotation shaft 171, thereby saving an assembly operation. A shape of the first connection member 172 may be cam-shaped, which facilitates a fixed connection between the first connection member 172 and the rigid member 191.

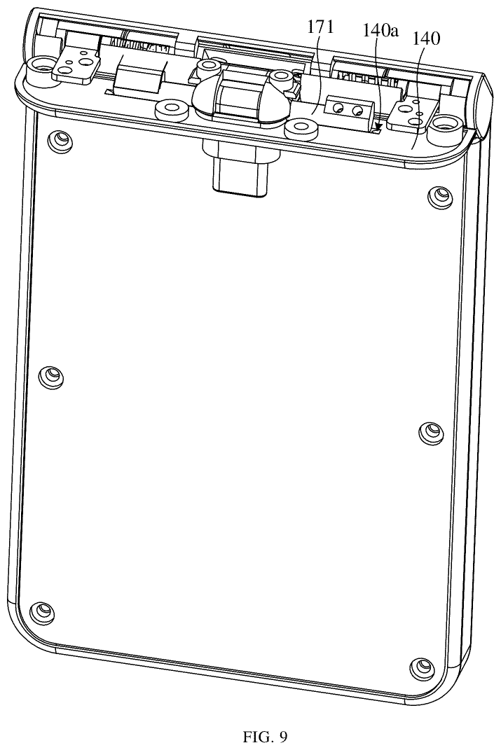

As illustrated in FIG. 9, in some embodiments, a wall surface of the second shell 140 defines an accommodation groove 140a, and the first rotation shaft 171 is at least partially accommodated in the accommodation groove 140a, so that a wall thickness of the second shell 140 can be configured to accommodate the first rotation shaft 171, thereby reducing a size of the second shell 140.

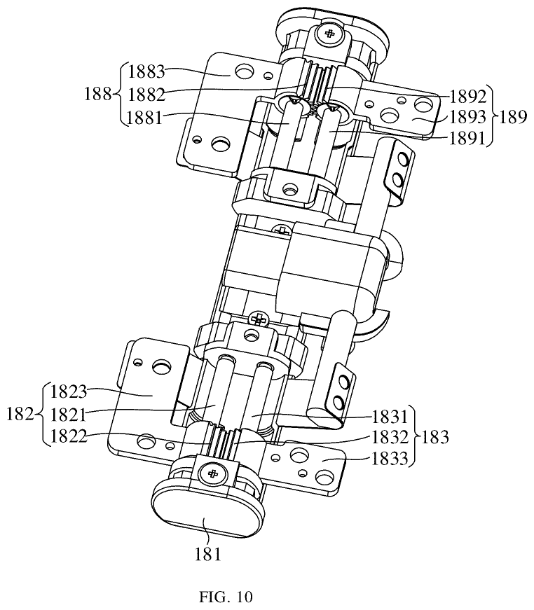

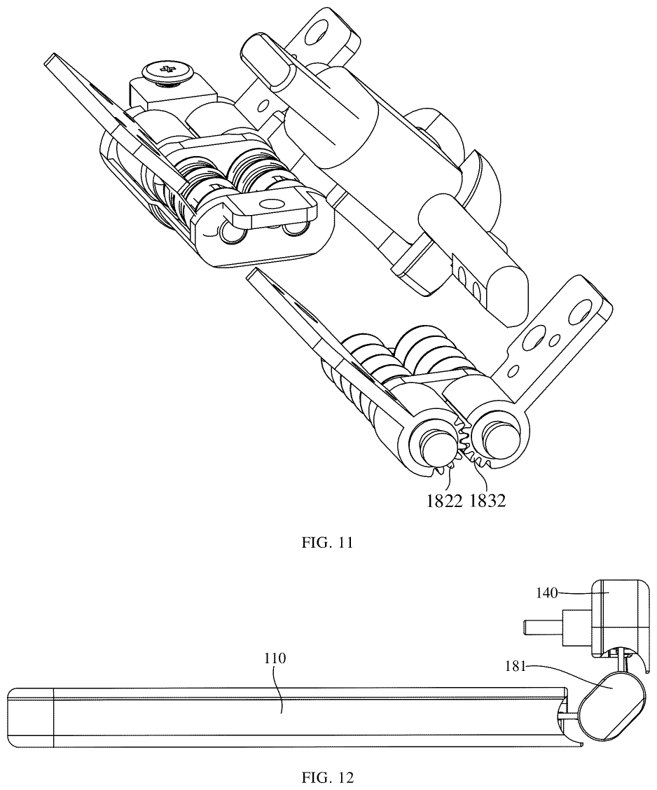

As illustrated in FIGS. 10 to 12, in some embodiments, the second rotation structure 180 includes a third shell 181, a first rotation assembly 182, and a second rotation assembly 183.

The third shell 181 is configured to support the first rotation assembly 182 and the second rotation assembly 183, so that an axis of the first rotation assembly 182 and an axis of the second rotation assembly 183 are relatively fixed.

The first rotation assembly 182 is rotatably disposed on the third shell 181, and the first rotation assembly 182 is connected to the first shell 110. In a case where the first rotation assembly 182 is rotated, it drives the first shell 110 to rotate. In some embodiments, the first rotation assembly 182 may be detachably connected to the first shell 110. In some embodiments, the first rotation assembly 182 may be connected to the first shell 110 through a screw, so that during assembly, the first rotation assembly 182 may be first assembled with the third shell 181, and then the third shell 181 may be assembled with the first shell 110, so as to reduce the assembly difficulty. In some embodiments, the first rotation assembly 182 may be integrated with the first shell 110 through injection molding, thereby reducing the assembly process.

The second rotation assembly 183 is rotatably disposed on the third shell 181, and the second rotation assembly 183 is connected to the second shell 140. In a case where the second rotation assembly 183 is rotated, it drives the second shell 140 to rotate. In some embodiments, the second rotation assembly 183 may be detachably connected to the second shell 140. In some embodiments, the second rotation assembly 183 may be connected to the second shell 140 through the screw, so that during assembly, the second rotation assembly 183 may be first assembled with the third shell 181, and then the third shell 181 may be assembled with the second shell 140, so as to reduce the assembly difficulty. In some embodiments, the second rotation assembly 183 may be integrated with the second shell 140 through the injection molding, thereby reducing the assembly process.

By disposing the first rotation assembly 182 and the second rotation assembly 183, the first shell 110 and the second shell 140 may be rotated around different rotation shafts, so that the first shell 110 and the second shell 140 may be spaced apart from each other, thereby avoiding interference between the first shell 110 and the second shell 140 during the rotation.

As illustrated in FIGS. 10-12, in some embodiments, the first rotation assembly 182 is in transmission connection with the second rotation assembly 183. That is, the first rotation assembly 182 and the second rotation assembly 183 are simultaneously rotated or simultaneously remain stationary, and a rotation direction of the first rotation assembly 182 and the rotation direction of a second rotation assembly 183 are opposite. In a case where the first rotation assembly 182 is rotated towards a direction close to the second rotation assembly 183, the second rotation assembly 183 is also rotated towards a direction close to the first rotation assembly 182. In a case where the first rotation assembly 182 is rotated towards a direction away from the second rotation assembly 183, the second rotation assembly 183 is also rotated towards a direction away from the first rotation assembly 182. Both the first rotation assembly 182 and the second rotation assembly 183 are disposed on the third shell 181, that is, both the first shell 110 and the second shell 140 are rotated relative to the third shell 181. An angle of rotation of the first shell 110 relative to the third shell 181 is relatively small, and an angle of rotation of the second shell 140 relative to the third shell 181 is relatively small. Therefore, it is beneficial for minimizing the gap between the first shell 110 and the third shell 181, as well as the gap between the second shell 140 and the third shell 181, so as to prevent debris from falling into an interior of the power bank 100 as much as possible.

As illustrated in FIGS. 10 to 12, in some embodiments, the first rotation assembly 182 includes a second rotation shaft 1821, a third gear 1822, and a second connection member 1823. The second connection member 1823 is connected to the third gear 1822 and the first shell 110, and a connection between the second connection member 1823 and the first shell 110 may be a screw connection. The second rotation shaft 1821 is rotatably disposed on the third shell 181, and the third gear 1822 is fixedly connected to the second rotation shaft 1821. In some embodiments, the second rotation shaft 1821 may be fixedly disposed on the third shell 181, and the third gear 1822 may be rotatably disposed on the second rotation shaft 1821, as long as the third gear 1822 may be rotated relative to the third shell 181. The third gear 1822 and the second connection member 1823 are connected to the third shell 181 through the second rotation shaft 1821, and the third gear 1822 and the second connection member 1823 may not be in contact with the third shell 181. In some embodiments, the rigid member 191 may be connected to the second rotation shaft 1821, so that the second rotation shaft 1821 can drive the rigid member 191 to move during its rotation.

The second rotation assembly 183 includes a third rotation shaft 1831, a fourth gear 1832, and a third connection member 1833. The third connection member 1833 is connected to the fourth gear 1832 and the second shell 140, and a connection between the third connection member 1833 and the second shell 140 may be the screw connection. The third rotation shaft 1831 is rotatably disposed on the third shell 181, and the fourth gear 1832 is fixedly connected to the third rotation shaft 1831. In some embodiments, the third rotation shaft 1831 may be fixedly disposed on the third shell 181, and the fourth gear 1832 may be rotatably disposed on the third rotation shaft 1831, as long as the fourth gear 1832 may be rotated relative to the third shell 181. The third gear 1822 meshes with the fourth gear 1832, thereby achieving the transmission connection between the first rotation assembly 182 and the second rotation assembly 183. The rotation direction of the first rotation assembly 182 is opposite to that of the second rotation assembly 183. The fourth gear 1832 and the third connection member 1833 are connected to the third shell 181 through the third rotation shaft 1831, and the fourth gear 1832 and the third connection member 1833 may not be in contact with the third shell 181. In some embodiments, the rigid member 191 may be connected to the third rotation shaft 1831, so that the third rotation shaft 1831 can drive the rigid member 191 to move during its rotation.

As illustrated in FIGS. 10 to 12, in some embodiments, the second rotation structure 180 further includes a third rotation assembly 188 and a fourth rotation assembly 189.

The third shell 181 is configured to support the third rotation assembly 188 and the fourth rotation assembly 189, so that an axis of the third rotation assembly 188 and an axis of the fourth rotation assembly 189 are relatively fixed.

The third rotation assembly 188 is rotatably disposed on the third shell 181, and the third rotation assembly 188 is connected to the first shell 110. In a case where the third rotation assembly 188 is rotated, it drives the first shell 110 to rotate. In some embodiments, the third rotation assembly 188 may be detachably connected to the first shell 110. In some embodiments, the third rotation assembly 188 may be connected to the first shell 110 through the screw, so that during assembly, the third rotation assembly 188 may be first assembled with the third shell 181, and then the third shell 181 may be assembled with the first shell 110, so as to reduce the assembly difficulty. In some embodiments, the third rotation assembly 188 may be integrated with the first shell 110 through the injection molding, thereby reducing the assembly process.

The fourth rotation assembly 189 is rotatably disposed on the third shell 181, and the fourth rotation assembly 189 is connected to the second shell 140. In a case where the fourth rotation assembly 189 is rotated, it drives the second shell 140 to rotate. In some embodiments, the fourth rotation assembly 189 may be detachably connected to the second shell 140. In some embodiments, the fourth rotation assembly 189 may be connected to the second shell 140 through the screw, so that during assembly, the fourth rotation assembly 189 may be first assembled with the third shell 181, and then the third shell 181 may be assembled with the second shell 140, so as to reduce the assembly difficulty. In some embodiments, the fourth rotation assembly 189 may be integrated with the second shell 140 through the injection molding, thereby reducing the assembly process.

By disposing the third rotation assembly 188 and the fourth rotation assembly 189, the first shell 110 and the second shell 140 may be rotated around different rotation shafts, so that the first shell 110 and the second shell 140 may be spaced apart from each other, thereby avoiding the interference between the first shell 110 and the second shell 140. The first shell 110 and the second shell 140 can be more stable during rotation.

As illustrated in FIGS. 10 to 12, in some embodiments, the third rotation assembly 188 is in transmission connection with the fourth rotation assembly 189. That is, the third rotation assembly 188 and the fourth rotation assembly 189 are simultaneously rotated or simultaneously remain stationary, and a rotation direction of the third rotation assembly 188 is opposite to that of the fourth rotation assembly 189. In a case where the third rotation assembly 188 is rotated towards a direction close to the fourth rotation assembly 189, at the same time, the fourth rotation assembly 189 is also rotated towards a direction close to the third rotation assembly 188. In a case where the third rotation assembly 188 is rotated in a direction away from the fourth rotation assembly 189, at the same time, the fourth rotation assembly 189 is also rotated in a direction away from the third rotation assembly 188. Both the third rotation assembly 188 and the fourth rotation assembly 189 are located in the third shell 181, that is, both the first shell 110 and the second shell 140 are rotated relative to the third shell 181. The angle of rotation of the first shell 110 relative to the third shell 181 is relatively small, and the angle of rotation of the second shell 140 relative to the third shell 181 is relatively small. Therefore, it is beneficial for minimizing the gap between the first shell 110 and the third shell 181, as well as the gap between the second shell 140 and the third shell 181, so as to prevent the debris from falling into the interior of the power bank 100 as much as possible.

As illustrated in FIGS. 10 to 12, in some embodiments, the third rotation assembly 188 includes a fourth rotation shaft 1881, a fifth gear 1882, and a fourth connection member 1883. The fourth connection member 1883 is connected to the fifth gear 1882 and the first shell 110, and a connection between the fourth connection member 1883 and the first shell 110 may be the screw connection. The fourth rotation shaft 1881 is rotatably disposed on the third shell 181, and the fifth gear 1882 is fixedly connected to the fourth rotation shaft 1881. In some embodiments, the fourth rotation shaft 1881 may be fixedly disposed on the third shell 181, and the fifth gear 1882 may be rotatably disposed on the fourth rotation shaft 1881, as long as the fifth gear 1882 may be rotated relative to the third shell 181. The fifth gear 1882 and the fourth connection member 1883 are connected to the third shell 181 through the fourth rotation shaft 1881, and the fifth gear 1882 and the fourth connection member 1883 may not be in contact with the third shell 181.

The fourth rotation assembly 189 includes a fifth rotation shaft 1891, a sixth gear 1892, and a fifth connection member 1893. The fifth connection member 1893 is connected to the sixth gear 1892 and the second shell 140, and a connection between the fifth connection member 1893 and the second shell 140 may be the screw connection. The fifth rotation shaft 1891 is rotatably disposed on the third shell 181, and the sixth gear 1892 is fixedly connected to the fifth rotation shaft 1891. In some embodiments, the fifth rotation shaft 1891 may be fixedly disposed on the third shell 181, and the sixth gear 1892 may be rotatably disposed on the fifth rotation shaft 1891, as long as the sixth gear 1892 may be rotated relative to the third shell 181. The fifth gear 1882 meshes with the sixth gear 1892, thereby achieving the transmission connection between the third rotation assembly 188 and the fourth rotation assembly 189. The rotation direction of the third rotation assembly 188 is opposite to that of the fourth rotation assembly 189. The sixth gear 1892 and the fifth connection member 1893 are connected to the third shell 181 through the fifth rotation shaft 1891, and the sixth gear 1892 and the fifth connection member 1893 may not be in contact with the third shell 181.

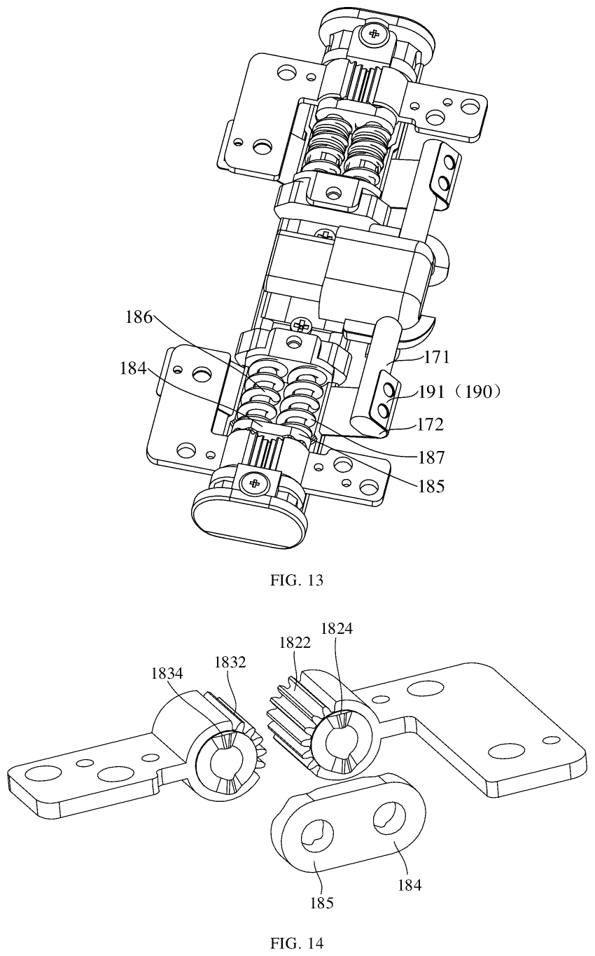

As illustrated in FIGS. 13 to 15, in some embodiments, a first fitting part 1824 is disposed on the first rotation assembly 182, and the power bank 100 further includes a first limiting member 184. The first limiting member 184 and the first fitting part 1824 are configured to limit and cooperate, thereby limiting the rotation of the first rotation assembly 182. The first fitting part 1824 may be a first limiting protrusion disposed on a side surface of the third gear 1822, and the first limiting member 184 may define a first limiting groove. The first limiting protrusion is in a limiting fit with the first limiting groove, so that the first shell 110 and the third shell 181 remain relatively stationary. In some embodiments, the number of the first limiting protrusions and the number of the first limiting grooves may be multiple, and multiple first limiting protrusions are in one-to-one correspondence with multiple first limiting grooves, thereby achieving a better limit effect.

As illustrated in FIGS. 13 to 15, in some embodiments, a second fitting part 1834 is disposed on the second rotation assembly 183, and the power bank 100 further includes a second limiting member 185. The second limiting member 185 and the second fitting part 1834 are configured to limit and cooperate, thereby limiting the rotation of the second rotation assembly 183. The second fitting part 1834 may be a second limiting protrusion disposed on a side surface of the fourth gear 1832, and the second limiting member 185 may define a second limiting groove. The second limiting protrusion is in the limiting fit with the second limiting groove, so that the second shell 140 and the third shell 181 remain relatively stationary. In some embodiments, the number of the second limiting protrusions and the number of the second limiting grooves may be multiple, and multiple second limiting protrusions are in one-to-one correspondence with multiple second limiting grooves, thereby achieving a better limit effect.

In some embodiments, the first limiting member 184 is sleeved on the second rotation shaft 1821, and the second limiting member 185 is sleeved on the third rotation shaft 1831. The power bank 100 further includes a first elastic member 186 and a second elastic member 187. Two ends of the first elastic member 186 are respectively in contact with the first limiting member 184 and the third shell 181. The first elastic member 186 presses the first limiting member 184 against the third gear 1822. Two ends of the second elastic member 187 are respectively in contact with the second limiting member 185 and the third shell 181, and the second elastic member 187 presses the second limiting member 185 against the fourth gear 1832.

In some embodiments, in a case where the first shell 110 and the third shell 181 remain relatively stationary and the second shell 140 and the third shell 181 remain relatively stationary, the first shell 110 and the second shell 140 may remain relatively stationary. In some embodiments, the power bank 100 may be limited in the first state or the second state.

In some embodiments, the first limiting member 184 may be integrated with the second limiting member 185, thereby reducing the number of components in the power bank 100.

As illustrated in FIG. 16, in some embodiments, the second rotation structure 180 includes a sixth rotation shaft 1894.

The sixth rotation shaft 1894 may be rotatably disposed on the first shell 110, and the sixth rotation shaft 1894 may be fixedly connected to the second shell 140.

In some embodiments, the sixth rotation shaft 1894 may be rotatably disposed on the second shell 140, and the sixth rotation shaft 1894 may be fixedly connected to the first shell 110.

In some embodiments, the sixth rotation shaft 1894 may be rotatably disposed on the first shell 110, and the sixth rotation shaft 1894 may be rotatably disposed on the second shell 140.

That is, the second rotation structure 180 is designed as a single rotation shaft. Therefore, the second rotation structure 180 has a relatively simple structure, lower production costs, and occupies less space, which is conducive to the miniaturization of the power bank 100.

In some embodiments, as illustrated in FIGS. 19 and 20, the power bank 100 further includes a first driving member 1104, and the first driving member 1104 is in transmission connection with the first rotation structure 170 and configured to drive the connection terminal 150 to rotate relative to the second shell 140. The first driving member 1104 may be a first motor, thereby driving the connection terminal 150 to automatically fold or unfold.

In some embodiments, the first driving member 1104 is simultaneously in transmission connection with the first rotation structure 170 and the second rotation structure 180, so as to drive the connection terminal 150 to rotate relative to the second shell 140, and to drive the first shell 110 to rotate relative to the second shell 140.

In some embodiments, the power bank 100 further includes a second driving member 1106, and the second driving member 1106 is in transmission connection with the second rotation structure 180 and configured to drive the first shell 110 to rotate relative to the second shell 140. The second driving member 1106 may be a second motor, thereby driving the power bank 100 to automatically fold or unfold.

In a case where the power bank 100 is provided with the linkage structure 190, the power bank 100 only needs to be provided with one of the first driving member 1104 and the second driving member 1106, which can drive the connection terminal 150 to rotate relative to the second shell 140, and simultaneously drive the first shell 110 to rotate relative to the second shell 140.

In some embodiments, the power bank 100 may be simultaneously provided with the first driving member 1104 and the second driving member 1106. The first driving member 1104 is in transmission connection with the first rotation structure 170, and the second driving member 1106 is in transmission connection with the second rotation structure 180, so that the first driving member 1104 and the second driving member 1106 can drive the power bank 100 to be automatically folded or unfolded.

The effects of the present disclosure are as follows. The first shell is able to be rotated relative to the second shell through the first rotation structure, and the connection terminal is able to be rotated relative to the second shell through the second rotation structure. Therefore, in a case where charging is required, the first shell can be rotated to form an angle with the second shell, and the connection terminal can be rotated to be substantially parallel to the first shell. In a case where the electronic device establishes plug-in cooperation with the connection terminal, the first shell can be in contact with a front surface or a back surface of the electronic device, providing support for the electronic device, thereby ensuring high stability during charging the electronic device.

The above descriptions are only some preferred embodiments of the present disclosure and are not intended to limit the protection scope of the present disclosure. Under the concept of the present disclosure, any equivalent structural transformation made by using the contents of specification and accompanying drawings of the present disclosure, or directly or indirectly applied in other related technical fields, are included in the protection scope of the present disclosure.

1. A power bank, comprising:
a first shell;
a battery;
a circuit board, electrically connected to the battery, wherein the battery and the circuit board are disposed inside the first shell;
a second shell, disposed on a side of the first shell;
a connection terminal, disposed on the second shell, wherein the connection terminal comprises an input end and an output end electrically connected to the input end;
an electrical connection assembly, electrically connected to the input end of the connection terminal and the circuit board, wherein the power bank is able to be in a first state; and in a case where the power bank is in the first state, the output end of the connection terminal is disposed facing the first shell;
a first rotation structure, connected to the connection terminal and the second shell, so that the connection terminal is able to be rotated relative to the second shell; and
a second rotation structure, connected to the first shell and the second shell, so that the first shell is able to be rotated relative to the second shell.

2. The power bank according to claim 1, wherein the second rotation structure is disposed between the first shell and the first rotation structure.

3. The power bank according to claim 1, further comprising a linkage structure, wherein the linkage structure is connected to the first rotation structure and the second rotation structure, and the second rotation structure is able to drive the first rotation structure to rotate through the linkage structure.

4. The power bank according to claim 3, wherein the power bank is further able to be in a second state; and in a case where the power bank is rotated from the first state to the second state, the second rotation structure is configured to drive the linkage structure to pull the first rotation structure to rotate.

5. The power bank according to claim 4, wherein in a case where the power bank is rotated from the second state to the first state, the linkage structure is configured to push the first rotation structure to rotate.

6. The power bank according to claim 5, wherein the linkage structure comprises a rigid member, the rigid member is able to experience elastic deformation, so that the rigid member is able to partially surround or be unfold from the first rotation structure;
in a case where the power bank is rotated from the first state to the second state, the second rotation structure is configured to drive the rigid member to deform, so that the first rotation structure is pulled to rotate; and
in a case where the power bank is rotated from the second state to the first state, the second rotation structure is configured to drive the rigid member to recover deformation, so that the first rotation structure is pushed to rotate.

7. The power bank according to claim 4, wherein the power bank further comprises a reset member, the reset member is connected to the connection terminal and the second shell, or the reset member is connected to the first rotation structure and the second shell, so that the connection terminal has a restoring force that is configured to rotate the connection terminal to be parallel to the second shell.

8. The power bank according to claim 3, wherein the linkage structure comprises:
a first gear, connected to the first rotation structure and rotated synchronously with the first rotation structure; and
a second gear, connected to the second rotation structure and rotated synchronously with the second rotation structure, wherein the first gear meshes with the second gear.

9. The power bank according to claim 1, wherein the first rotation structure comprises a first rotation shaft, the connection terminal is connected to the first rotation shaft, the first rotation shaft is rotatably disposed on the second shell, an accommodation groove is defined on a wall surface of the second shell, and at least a part of the first rotation shaft is accommodated in the accommodation groove.

10. The power bank according to claim 3, wherein the first rotation structure comprises a first rotation shaft and a first connection member disposed on the first rotation shaft, the first rotation shaft is rotatably disposed on the second shell, and the linkage structure is connected to the first connection member and drives the first rotation shaft to rotate through the first connection member.

11. The power bank according to claim 1, wherein the second rotation structure comprises:
a third shell;
a first rotation assembly, rotatably disposed on the third shell and connected to the first shell; and
a second rotation assembly, rotatably disposed on the third shell and connected to the second shell.

12. The power bank according to claim 11, wherein the first rotation assembly is in transmission connection with the second rotation assembly, and a rotation direction of the first rotation assembly is opposite to that of the second rotation assembly.

13. The power bank according to claim 12, wherein
the first rotation assembly comprises a second rotation shaft, a third gear, and a second connection member, and the second connection member is connected to the third gear and the first shell;
the second rotation shaft is rotatably disposed on the third shell, and the third gear is fixedly connected to the second rotation shaft; or the second rotation shaft is fixedly disposed on the third shell, and the third gear is rotatably disposed on the second rotation shaft;
the second rotation assembly comprises a third rotation shaft, a fourth gear, and a third connection member, and the third connection member is connected to the fourth gear and the second shell;
the third rotation shaft is rotatably disposed on the third shell, and the fourth gear is fixedly connected to the third rotation shaft; or the third rotation shaft is fixedly disposed on the third shell, and the fourth gear is rotatably disposed on the third rotation shaft; and
the third gear meshes with the fourth gear.

14. The power bank according to claim 11, wherein a first fitting part is disposed on the first rotation assembly, and the power bank further comprises a first limiting member, and the first limiting member is in a limiting fit with the first fitting part, so as to limit rotation of the first rotation assembly; and/or
the second rotation assembly is provided with a second fitting part, and the power bank further comprises a second limiting member, and the second limiting member is in a limiting fit with the second fitting part, so as to limit rotation of the second rotation assembly.

15. The power bank according to claim 11, wherein the second rotation structure comprises:
a third rotation assembly, rotatably disposed on the third shell and connected to the first shell; and
a fourth rotation assembly, rotatably disposed on the third shell and connected to the second shell.

16. The power bank according to claim 15, wherein
the third rotation assembly comprises a fourth rotation shaft, a fifth gear, and a fourth connection member, and the fourth connection member is connected to the fifth gear and the first shell;
the fourth rotation shaft is rotatably disposed on the third shell, and the fifth gear is fixedly connected to the fourth rotation shaft; or the fourth rotation shaft is fixedly disposed on the third shell, and the fifth gear is rotatably disposed on the fourth rotation shaft;
the fourth rotation assembly comprises a fifth rotation shaft, a sixth gear, and a fifth connection member, and the fifth connection member is connected to the sixth gear and the second shell;
the fifth rotation shaft is rotatably disposed on the third shell, and the sixth gear is fixedly connected to the fifth rotation shaft; or the fifth rotation shaft is fixedly disposed on the third shell, and the sixth gear is rotatably disposed on the fifth rotation shaft; and
the fifth gear meshes with the sixth gear.

17. The power bank according to claim 1, wherein the second rotation structure comprises a sixth rotation shaft;
the sixth rotation shaft is rotatably disposed on the first shell, and the sixth rotation shaft is fixedly connected to the second shell; or
the sixth rotation shaft is rotatably disposed on the second shell, and the sixth rotation shaft is fixedly connected to the first shell; or
the sixth rotation shaft is rotatably disposed on the first shell, and the sixth rotation shaft is rotatably disposed on the second shell.

18. The power bank according to claim 1, wherein the power bank is further able to be in a second state; and in a case where the power bank is in the first state, the first shell is disposed parallel to the second shell, and the connection terminal is disposed parallel to the second shell; and
in a case where the power bank is in the second state, the first shell is disposed perpendicular to the second shell, and the connection terminal is disposed parallel to the first shell and at least partially extends out of the second shell.

19. The power bank according to claim 1, wherein rotation amplitude of the connection terminal relative to the second shell is the same as rotation amplitude of the first shell relative to the second shell; and/or
a rotation direction of the connection terminal relative to the second shell is the same as a rotation direction of the first shell relative to the second shell.

20. The power bank according to claim 1, wherein the power bank further comprises a first driving member, and the first driving member is in transmission connection with the first rotation structure, so as to drive the connection terminal to rotate relative to the second shell; and/or
the power bank further comprises a second driving member, and the second driving member is in transmission connection with the second rotation structure, so as to drive the first shell to rotate relative to the second shell.
